(19) United States
(12) Patent Application Publication
(10) Pub. No.: US 2019/0348597 A1
(43) Pub. Date: Nov. 14, 2019

(54) Piezoelectricity-induced High Temperature Superconductor

(71) Applicant: Salvatore Cezar Pais, Callaway, MD (US)

(72) Inventor: Salvatore Cezar Pais, Callaway, MD (US)

(73) Assignee: United States of America as represented by the Secretary of the Navy, Patuxent River, MD (US)

(21) Appl. No.: 16/519,136

(22) Filed: Jul. 23, 2019

Related U.S. Application Data
(63) Continuation of application No. 15/678,672, filed on Aug. 16, 2017.

(51) Int. Cl. H01L 41/107; H01L 41/08; H01B 12/06

(52) U.S. Cl. CPC H01L 41/107; H01B 12/06; H01L 41/0805

(57) ABSTRACT

The present invention is a high temperature superconductor comprising of a wire, which comprises of an insulator core and a metal coating. The metal coating is disposed around the insulator core, and the metal is coating deposited on the core. When a pulsed current is passed through the wire, while the wire is vibrated, high temperature superconductivity is induced.

### CROSS-REFERENCES

The present application is a continuation-in-part of U.S. patent application Ser. No. 15/678,672 entitled “Piezoelectricity-induced Room Temperature Super Conductor,” filed on Aug. 16, 2017. The present application is related to copending application Ser. No. 15/678,672, which is incorporated herein by reference, and has the same inventor.

### STATEMENT OF GOVERNMENT INTEREST

The invention described herein may be manufactured and used by or for the Government of the United States of America for governmental purposes without payment of any royalties thereon or therefor.

### BACKGROUND

A high temperature superconductor is a material that is capable of exhibiting superconductivity at operating temperatures of or above 25° C. (approx. 300° K). Several materials have been reported to be room-temperature superconductors, although none of these reports has been confirmed. However, instead of concentrating on the chemical structure of such materials which do not utilize any electrical or mechanical manipulation, high temperature superconductivity (HTSC) in a manipulated current-carrying special composite metal wire may be achieved. The current must be pulsed for maximum effect. This concept enables the transmission of electrical power without any losses and exhibits optimal thermal management (no heat dissipation), which leads to the design and development of novel energy generation and harvesting devices with enormous benefits to civilization.

Simply put, HTSC can be enabled in a current carrying special composite metal wire which is abruptly vibrated by mechanical, magnetic, electrical, and/or electromagnetic means. The wire is a bulk (core) insulator with a ‘thin’ coating of a normal metal (such as Aluminum) or other practicable coating. The coating has a thickness on the order of the London penetration depth (but possibly much thicker), and an externally applied magnetic field is applied to the metal. For the electrically-driven vibration, the wire is coated with lead zirconate titanate (PZT ceramic/poor metal), or any other material in which the piezoelectric effect can be induced. Since the HTSC supercurrent may be generated along the metal/insulator interface (boundary), this wire configuration can be termed an unconventional superconductor.

The achievement of high temperature superconductivity (HTSC) represents a highly disruptive technology, capable of a total paradigm change in Science and Technology, rather than just a paradigm shift. Hence, its military and commercial value is considerable.

### SUMMARY

The present invention is directed to a piezoelectricity-induced high temperature superconductor with the needs enumerated above and below.

The present invention is directed to a piezoelectricity-induced high temperature superconductor that includes a wire comprising an insulator core and a coating, the coating disposed around the insulator core, the coating deposited on the core, the coating undergoes polarizing treatment after the deposition, and, when a pulsed current is passed through the wire, high temperature superconductivity is induced.

It is a feature of the present invention to provide a piezoelectricity-induced high temperature superconductor that enables the transmission of electrical power with no losses.

It is a feature of the present invention to provide a piezoelectricity-induced high temperature superconductor that superconductivity is achieved from abrupt/accelerated vibration of a wire through use of a pulsed current through the wire.

### DRAWINGS

These and other features, aspects and advantages of the present invention will become better understood with reference to the following description and appended claims, and accompanying drawings wherein

FIG. 1 is an embodiment of the piezoelectricity-induced high temperature superconductor; and,

FIG. 2 is another embodiment of the vibration-induced high temperature superconductor.

### DESCRIPTION

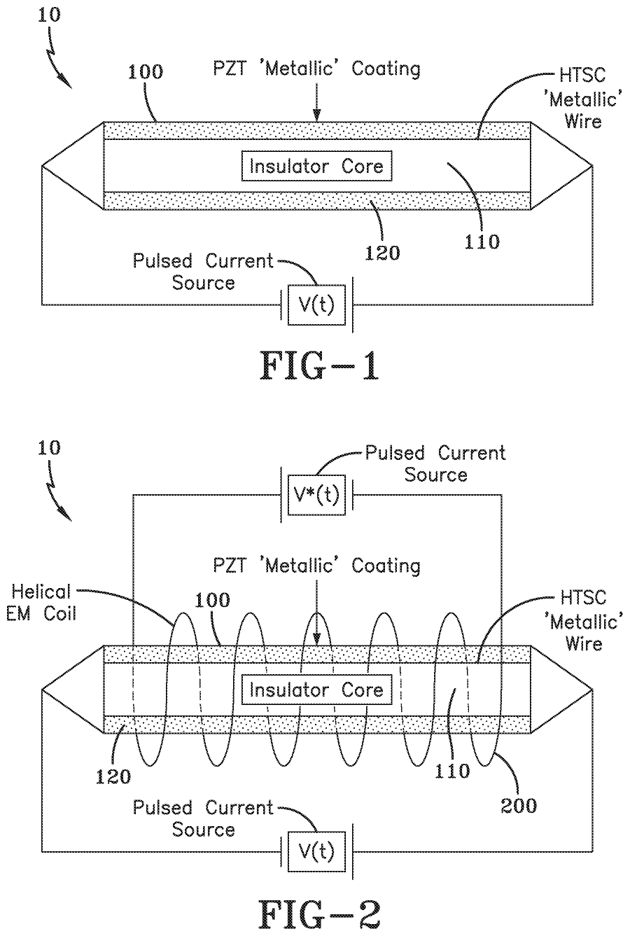

The preferred embodiments of the present invention are illustrated by way of example below and in FIGS. 1-2. As shown in FIG. 1, the piezoelectricity-induced high temperature superconductor 10 includes a wire 100 comprising an insulator core 110 and a coating 120 (the coating may be a lead zirconate titanate (PZT) coating, Aluminum, or any other material that induces the piezoelectric effect). The coating 120 disposed around the insulator core 110, and the coating 120 is deposited on the core 110. The coating 120 undergoes polarizing treatment after the deposition, and when a pulsed current is passed through the wire 100, high temperature superconductivity is induced.

In the description of the present invention, the invention will be discussed in a laboratory environment; however, this invention can be utilized for any type of application that requires a conductor.

The enablement of HTSC relates to the superconducting (SC) material chemical structure, but a great deal more to do with what is ‘done’ to the material to make it SC, from a far-from-equilibrium perspective (non-equilibrium thermodynamics). It is important to realize that internal heating within any system enclosure can be greatly reduced by high temperature (300 deg. Kelvin and higher) superconducting wiring, which would allow for lossless transmission of electrical power to its subsystems.

There are three parameters which affect superconductivity. The parameters include temperature, current density, and externally applied magnetic field strength. Physically, these parameters have in common one thing, that is, the interactive motion of electric charges, namely electrons. Control of this motion via vibration and/or spin of charged matter subjected to rapid acceleration transients (highly non-linear in nature) may lead to the achievement of high temperature superconductivity, especially if the charged matter is inhomogeneous.

At the present time, it is believed that the mechanism of superconductivity can be induced either by bipolarons or Cooper pairing. A bipolaron can be defined, but without limitation, as a quasiparticle consisting of two polarons. A polaron is, but without limitation, a quasiparticle used in condensed matter physics to understand the interactions between electrons and atoms in a solid material. A Cooper pair or BCS pair is a pair of electrons (or other fermions) bound together at low temperatures. An arbitrarily small attraction between electrons in a metal can cause a paired state of electrons to have a lower energy than the Fermi energy, which implies that the pair is bound. In conventional (BCS) superconductors, this attraction is due to the electron-phonon interactions. The important realization is that independent of physical mechanism, the key to observed superconductivity is the strong electron-lattice (phonon) coupling. Strong electron-lattice interactions can be obtained from abrupt/accelerated vibration of a wire; thereby, providing justification for HTSC enablement. As a result, a special composite metallic wire can become superconductive (SC) at high temperature, if you make it abruptly vibrate, while running a pulsed current through it, just like ‘plucking’ a guitar string intermittently. The current must be pulsed for maximum effect.

In one of the embodiments of the invention, the wire 100 is a special composite metal wire that may be comprised of a bulk (core) insulator 110 (such as Teflon, or any other non-conductive polymer) with a ‘thin’ coating 120 of a normal metal (aluminum) or poor metal (PZT ceramic). The coating 120 has a thickness on the order of the below described London penetration depth (but possibly much thicker), and the wire 100 is given an externally applied magnetic field. Arguably, this wire configuration may be termed an unconventional superconductor, since the HTSC supercurrent may be generated along the interface (boundary) between the coating 120 and the core insulator 110 of the wire. This is due to the abrupt change in state between the coating 120 and the insulator core 110, analogous to an abrupt phase transition occurring along the coating/insulator interface, which spontaneously breaks symmetry and thereby induces superconductivity. This abrupt change in state (phase transition) occurs as the wire 100 is abruptly vibrated and occurs at the boundary between the coating 120 and the bulk insulator 110, as various states of charged matter (coating 120) and non-charged (insulator core 110) matter are thrown into a state of coherent superposition.

As shown in Equation 1, the expression for the London penetration depth (λ_{L}) can be written as:

λ_{L}=[m_{S}(μ₀n_{S}q_{S}²)]^{1/2} (Equation 1),

wherein, m_{S} is the mass of the superconducting charge carriers (electrons), where μ₀ is the magnetic permeability of free space, n_{S} is the number density of superconducting charge carriers, and q_{S} is e or the electron charge.

Given that the superconducting charge carriers (of mass m_{S}, where μ₀ is the magnetic permeability of free space) are electrons (q_{S}=e, electron charge), with a number density of superconducting charge carriers (n_{S}) on the order of 10²⁰/cm³ (endemic of unconventional superconductors such as Yttrium Barium Copper Oxide or YBCO), the London penetration depth, and hence the thickness of the coating 120 of the wire 100 is on the order of micron(s). However, this thickness could be much greater, if practicable.

Consider an experimental set-up at standard high temperature and pressure, where a current carrying Al-coated wire (in a cylindrical configuration) is mechanically vibrated in an abrupt/accelerated manner by being struck with a non-conductive element, such as a Teflon pick, in order to generate accelerated vibrations. A more effective means of vibrating a wire in tension is by use of an electromagnetic (EM) plucking coil located in close proximity to the wire. The coil is rapidly energized and de-energized using either DC or AC current. The induced magnetic flux couples with the wire. Additionally, the wire coating can be doped with ferrite inclusions (species), such as, but not limited to iron or steel. Alternatively, the wire coating can be doped with sub-micron sized ferrite particles so that is becomes highly responsive to the electro-magnetic (EM) forces exerted by the plucking coil. However, this EM method of vibration may not be conducive to HTSC, since the mechanically-plucked Al-coated composite wire may fail the Meissner effect test for superconductivity, and not be able to expel the flux lines of the externally applied magnetic field. Further consider the electrically-driven vibration version of this idea, whereby a non-Al coated wire coated with lead zirconate titanate (PZT) is abruptly vibrated by having an electrical potential difference applied along its PZT coating, thus inducing wire vibration via the piezoelectric effect. Coupling of both mechanical and non-mechanical vibrations in an accelerated vibration mode subjected to rapid acceleration transients can be considered for possible amplification of system non-linearities, which can induce spin fluctuations in the metallic portion of the wire. Moreover, it has been shown that micrometer-size PZT thin film deposits can excite high vibration frequencies, exceeding 100 MHz, which would generate high EM fluxes in an outward direction, from the surface of the current-carrying composite wire. This method of vibration would be greatly conducive to superconductivity, since enablement of the Meissner effect would be possible. The current through the wire 100 can be pulsed for maximum effect. An EM plucking coil can also be used in conjunction with this piezoelectrically driven wire vibration method, thus generating differential vibrations, in order to control and augment spin fluctuations and therefore mediate long range phase coherence, which along with electron pairing gives rise to the onset of high temperature superconductivity.

There are three characteristics that a material must possess in order to be superconductive, a state of matter which constitutes a macroscopic quantum phenomenon. Such a material occupies a unique place in condensed matter physics. The three characteristics are perfect diamagnetism (the Meissner effect), perfect electrical conductivity (zero electrical resistance), and macroscopic quantum coherence (the ability of a portion of the constituent particles—electrons in a superconductor to fall into lock step and move in a highly organized orderly fashion, in other words to form a macroscopic matter wave). Considering that the current carrying wire 100 is abruptly vibrated by mechanical or piezoelectric means, this will generate a magnetic field which would exclude (expel) the magnetic field lines of an externally applied magnetic field, thus enabling a condition of perfect diamagnetism (exhibiting the Meissner effect), thus the present invention meets the first requirement for superconductivity.

For the vibrated wire, as shown in Equation 2, the condition for the Meissner effect to occur can be expressed as the maximum magnetic flux density (induction) as compared to the maximum magnetic induction from an externally applied magnetic field, namely:

[(μ₀I/2πR)+(μ₀σAᵥωᵥ²Δt)]≥(B_{E})_{MAX} (Equation 2),

where μ₀ is the magnetic permeability of free space, I is a time independent current through the wire, R is the wire radius, σ is the wire surface charge density, Aᵥ is the accelerated vibration amplitude, ωᵥ is the accelerated vibration frequency, Δt is the total time interval for which the wire is vibrated, and (B_{E})_{MAX} is the magnetic induction from an externally applied magnetic field. Note that Equation 2 is not a function of temperature and thus not a function of T_{c} (the critical temperature below which the wire becomes superconductive), thus the condition for the Meissner effect (perfect diamagnetism) becomes possible at high temperature. It is important to also note that the main driving parameter in this expression is the accelerated vibration frequency (ωᵥ), which solely exhibits a second power (non-linear) term.

In the present invention, since only the coating 120 of the wire 110 carries a charge due to the current, in the insulator core 110 or wire bulk, there is no charge motion. This means that the magnetic induction within the insulator core 110 or wire bulk (B) is zero, hence dB/dt, the time rate of change of B is zero as well (the two conditions for deriving the London equation describing the superconducting state, from the Maxwell equations). From Faraday's law we obtain that the curl of the electric field under (dB/dt=0) condition is zero. Combining this result with the form of Ohm's law relating electric field strength with the product of current density and electrical resistivity (time independent), it can be shown that the electric field must be zero (since we have current) only under the condition of zero electrical resistivity, hence perfect electrical conductivity. Thus, the present invention meets the second requirement for superconductivity mentioned above.

The third requirement for superconductivity, namely the enablement of macroscopic quantum coherence is best described by the conventional BCS (Bardeen, Cooper, and Schrieffer) theory, as follows. As the current courses along the wire 100, particularly along the coating 120, the lattice ionic vibrations (electron-phonon interactions) will create an attractive force between electrons (of opposite spins and opposite momentum), which normally want to repel one another, due to Coulomb repulsion. Thus, electron pairs, named Cooper pairs, will be formed, which will subsequently condense into a single quantum mechanical state, represented by a unique wave function. This is equivalent with macroscopic quantum coherence and can be further exemplified by the creation of the ‘supercurrent’ in the ‘gap’ material of a Josephson junction. In the present invention, under high temperature conditions, the thermal agitations (fluctuations)-induced lattice vibrations will couple with the artificially induced (by purely mechanical or piezoelectric means) vibrations of the lattice ions, produced by the abrupt (accelerated) vibration of the wire 100, to generate a virtual ‘soup’ of fluctuations, a highly non-linear, far-from-equilibrium environment in the coating 120 of the wire 100.

It is a well-known facet of quantum field theory that everything can be described in quantum mechanical terms. The complex interactions between a physical system and its surroundings (environment), disrupt the quantum mechanical nature of a system and render it classical under ordinary observation. This process is known as decoherence. However, it is argued that we can retard (delay) decoherence (and possibly even suppress it—namely decouple a physical system from the environment) by accelerated spin and/or accelerated vibration of electrically charged matter under rapid acceleration transients. This may be the very condition to achieve a state of macroscopic quantum coherence, the idea being that we never let the system achieve thermodynamic equilibrium, by constantly delaying the onset of relaxation to equilibrium (hence the production of maximal entropy is delayed). The system may “violently” react by generating “anomalous” emergent phenomena, such as high temperature superconductivity.

The Prigogine effect as discussed in a peer-reviewed published paper by the inventor, “The high energy electromagnetic field generator” published in Int. J. Space Science and Engineering, Vol. 3, No. 4, 2015 pp. 312-317, teaches us that under three conditions, a chaotic system (the aforementioned ‘soup’ of fluctuations) can self-organize into an orderly state, equivalent to the state of macroscopic quantum coherence. These conditions are the existence of a highly non-linear medium, an abrupt departure far-from-thermodynamic equilibrium, and an energy flux (caused by the intermittent abrupt vibration of the wire) to maintain the process of self-organization (order from chaos). This shows that the present invention has macroscopic quantum coherence, fulfilling the final requirement for superconductivity. As shown above, all three conditions for superconductivity are met by the present invention, thus, as a result, high temperature superconductivity is herein established and enabled.

It is possible that the key to superconductivity (and especially HTSC) is the enablement of local macroscopic quantum coherence, namely the ability of a macroscopic object to act as if quantum mechanical in nature exhibiting such phenomena as superposition, entanglement, tunneling. In summary, one can argue that the synthesis of three physical mechanisms, namely the Meissner effect, the Cooper effect (or bipolaron formation), and the Prigogine effect leads directly to the possibility of high temperature superconductivity, at least in a special composite metal wire. Therefore, the HTSC super-current may be generated along the interface (boundary) between the normal or poor metal (coating 120) and the insulator portions (insulator core 110) of the wire 100.

To buttress our argument from an experimental perspective, a recently published paper by M. Mitrano et al., entitled “Possible light-induced superconductivity in K3C60 at high temperature” published in Nature 530, 461-464, on 25 Feb. 2016, shows that “by exciting metallic K3C60 (potassium doped fullerene) with mid-infrared optical pulses, we induce a large increase in carrier mobility, accompanied by the opening of a gap in the optical conductivity”; thus showing the importance of non-equilibrium phenomena in effecting high Tc superconductivity. Even though the fullerene is not a normal or poor metal (as described above), the pulsed light induced high Tc superconductivity is shown to be a direct result of the driving non-equilibrium dynamics, which our argument considers as essential for achievement of HTSC. Experimentally, we may replace the normal metal portion (coating 120) of the wire 110 with Graphene, and observe under what conditions, if at all, HTSC is obtained.

Analysis of the fine structure constant (which characterizes the strength of electromagnetic interactions between elementary particles), written in terms of the quantum of magnetic flux, results in the notion that it is the electric charge and its interactive motion within the quantum vacuum that is fundamental to the nature of our Cosmos. If we consider magnetic flux quantization, we can write for the fine structure constant (a):

α=e/ϕ₀ε₀c (Equation 3),

where e is the charge of the electron, ε₀ and c are the electrical permittivity and the speed of light (respectively) in free space and ϕ₀ is the quantum of magnetic flux. The term 4o may be written as h*/(2e), where h* is Planck's constant divided by 2π. The fact that the fine structure constant can be expressed as a function of (2e) shows how important the notion of electron pairing is in the composition of the Universe, and gives credence to the theory that the fundamental cosmic meta-structure may be thought of as a charged superfluid, in other words, a superconducting condensate. Therefore, by controlling this interactive motion under the non-equilibrium condition of charged matter subjected to rapid acceleration transients, numerous advancements in science and technology may arise, high temperature superconductivity being one such advance, arguably an Emergent Physical Phenomenon. Electron pairing is the keystone of superconductivity, without which its physical mechanism cannot stand. At high temperatures, it is only the moderately strong non-linear electron-phonon (lattice vibrations) interactions that can induce electron pairing. It may be possible that the electron pairing mechanism is not caused by an electron-phonon (phononic) coupling but by an electron-electron (electronic) coupling, which does not use phonon mediation to induce attraction between electrons. Phononic may be defined as, but without limitation, as phonon-like. It is of particular interest to note that such a purely electronic coupling was proposed to explain the superconductivity mechanism in a thin (a few atomic layers thick) metallic film deposited on a dielectric (insulator) substrate. Moreover, a hybrid coupling, both electronic and phononic in nature was suggested for explaining experimentally observed indications of near high temperature superconductivity (313° K) in the interface between a thin Aluminum film deposited on a PZT substrate.

Along with electron pairing, it is the existence of spin fluctuations which induces long range phase coherence in solids, thereby giving rise to superconductivity. In order to generate and amplify both non-linear electron-phonon interactions and spin fluctuations in superconducting solids at room or higher temperatures, we must produce strong electron-lattice interactions which may be achieved by abrupt vibration of a composite metallic wire, through which a current is abruptly pulsed. With these ideas in mind, consider the preferred embodiment of the inventive concept, namely a composite metallic wire 100 composed of an insulator core 110 overlaid with a thin coating 120 of lead zirconate titanate (PZT) piezoelectric ceramic, through which a current is flowing using a pulsed current source, as portrayed in FIG. 1. In one of the preferred embodiments, the PZT coating 120 is deposited on the insulator substrate by using a vacuum evaporation method.

The insulator core 110 can be made from Teflon or any other flexible polymer, which displays non-conductive properties. In other embodiments, the coating 120 may be barium strontium titanate (toxicity must be considered) or any other poor metallic/ceramic material which displays good piezoelectric characteristics (deformation under applied electrical potential difference).

In another embodiment, the PZT coating 120 may undergo a polarizing (poling) treatment prior to HTSC enablement, so that optimal domain alignment is obtained within the ceramic coating 120, ensuring vibration in one particular direction. Polarizing (poling) treatment may be conducted, but without limitation, by subjecting the coating 120 to a strong dc current electric field, slightly below the Curie temperature (approx. 200° C., but possibly as high as 360° C., depending on PZT ceramic composition). Furthermore, to increase the probability of vibration in one particular direction, as well as to alleviate the brittle nature of the ceramic material, the coating 120 may be composite PZT and a highly conductive polymer, such as p-Terphenyl. Alternatively, the coating 120 may be a layer of PZT disposed between two layers of aluminum, resulting in a wire design which may be planar rather than cylindrical in nature. This composite coating design would amplify piezoelectrically-induced vibrations and possibly render them unidirectional.

In another embodiment of the invention, the coating 120 may be a composite wire coating 20 made from aluminum, possibly doped with PZT and/or ferrite species, for amplification of spin fluctuations (non-linear magnetic effects). FIG. 2 shows another embodiment of the invention, which includes a helical coil 200 that is wound around the wire 100 or circumferentially positioned around the wire 100/coating 120, in such a manner as to induce a strong time-variant magnetic field in the wire, while current is being pulsed through the wire 100, as well as through the coil 200 at different frequencies. This excites highly non-linear modes of vibration in the wire 100, thereby amplifying spin fluctuations within the coating 120, which mediate long-range phase coherence, and may give rise to high temperature superconductivity. The helical coil 200 can be made from the same material as the wire 100, so that it can also become high temperature superconductive as current is pulsed through it.

It is of interest to consider the isotope effect in superconductors, for which the critical temperature T_{c} can be scaled with (M^{-a}), where the exponent (a) can be higher than 0.5 for unconventional superconductors (high T_{c} superconductors such as YBCO); for the sake of simplicity we have a=1, where M is the ionic mass. Considering a classical Newtonian second law expression using the Lorentz electromagnetic force (under accelerating vibration of frequency Ω), we can relate the vibrating mass (M) with its vibrating charge (Q), in that (M) becomes directly proportional to the square of the ratio (Q/Ω). Therefore, it can be observed that the value of T_{c} can be directly proportional with the square of the vibrational frequency of the ionic mass, indicative of high T_{c} enablement with accelerating vibration of the wire.

In order to understand the electron pairing mechanism in the present invention, consider a simplified model for the ionic crystal lattice of the wire coating 120 which features a matrix of two rows and multiple columns of positive ions. Through this matrix, two fast electrons (pulsed current) move horizontally, a front electron and a rear electron. Recall that the current is abruptly pulsed through the metallic portion of the wire 100, while the wire 100 is abruptly vibrated. This means that the lattice ions will be moving furiously toward each other, in the direction of wire vibration which for the sake of simplicity, say that is vertical in motion (the frequency of pulsed current must be higher than the frequency of wire vibration). It is important to realize that for high frequencies of wire vibration, the thermal energy given by the Boltzmann relation (E=k T), where k is the Boltzmann constant (8.62×10⁻⁵ eV/° K) and T is high temperature (300° K), is far exceeded by the vibration energy of the wire. This means that the most important fluctuations are those of the lattice ions themselves, induced by the wire vibration. As the top and bottom lattice ions approach each other vigorously, they just as strongly rebound due to the Coulomb repulsion force acting between them. When the front electron approaches the gap between the two ions, the front electron is fast enough to pass through the ion gap and not collide with the lattice, because the electron speed is determined by the pulsed current. However, as the two lattice ions approach each other (permitting the front electron through), an enhanced positive charge region is formed between them. It is this enhanced positive charge region which decelerates the front electron while accelerating the rear electron toward it. As the two electrons approach each other, they pair up at much higher energies then Cooper pair formation (>10⁻³ eV). This results in creating a superconductive condition at high temperature.

When introducing elements of the present invention or the preferred embodiment(s) thereof, the articles “a,” “an,” “the,” and “said” are intended to mean there are one or more of the elements. The terms “comprising,” “including,” and “having” are intended to be inclusive and mean that there may be additional elements other than the listed elements.

Although the present invention has been described in considerable detail with reference to certain preferred embodiments thereof, other embodiments are possible. Therefore, the spirit and scope of the appended claims should not be limited to the description of the preferred embodiment(s) contained herein.

What is claimed is:

1. A high temperature superconductor comprising:
a wire comprising an insulator core and a metal coating, the metal coating disposed around the insulator core, the metal coating deposited on the core, and, when a pulsed current is passed through the wire while the wire is vibrated, high temperature superconductivity is induced.

2. A piezoelectricity-induced high temperature superconductor comprising:
a wire comprising an insulator core and a PZT coating, the PZT coating disposed around the insulator core, the PZT coating deposited on the core, the PZT coating undergoes polarizing treatment after deposition, and, when a pulsed current is passed through the wire, high temperature superconductivity is induced.

3. The superconductor of claim 2, wherein the PZT coating is deposited on the core by vacuum evaporation.

4. The superconductor of claim 2, wherein the coating has a thickness on the order of the London penetration depth.

5. The superconductor of claim 1, wherein the wire coating is a material in which the piezoelectric effect can be induced.

6. The superconductor of claim 1, wherein the superconductor further comprises an electromagnetic coil, the electromagnetic coil circumferentially positioned around the metal coating, such that when the electromagnetic coil is activated, a non-linear vibration of the superconductor is induced, enabling high temperature superconductivity.

7. The superconductor of claim 1, wherein the coating is aluminum.

8. The superconductor of claim 1, wherein the coating has a thickness on the order of the London penetration depth.
